(19) United States
(12) Patent Application Publication
(10) Pub. No.: US 2024/0030043 A1
(43) Pub. Date: Jan. 25, 2024

(54) NEUTRAL BEAM ANNEALING APPARATUS AND METHOD OF MANUFACTURING DISPLAY APPARATUS USING THE SAME

(71) Applicant: SAMSUNG DISPLAY CO., LTD., Yongin-si (KR)

(72) Inventor: Takayuki FUKASAWA, Yongin-si (KR)

(21) Appl. No.: 18/224,141

(22) Filed: Jul. 20, 2023

(30) Foreign Application Priority Data
Jul. 20, 2022 (KR) 10-2022-0089683

(51) Int. Cl. H01L 21/477; H01J 37/32

(52) U.S. Cl. CPC H01L 21/477; H01J 37/32449; H01J 37/32816; H01J 37/32568; H01J 37/3211; H01J 2237/336; H01J 2237/182

(57) ABSTRACT

A neutral beam annealing apparatus includes a plasma chamber having a cylinder shape, a first gas supplier to supply a first gas for forming plasma, a first electrode coupled to an upper surface of the plasma chamber, an induction coil wound around an outer circumference of the plasma chamber to receive a high-frequency voltage from a high-frequency power supply, a second electrode which is coupled to a lower surface of the plasma chamber, and in which through holes are defined, a substrate support supporting a substrate to be annealed and adjusting a vertical distance between the substrate and the second electrode, an annealing chamber accommodating the substrate support, and a pressure controller which supplies a second gas to the annealing chamber.

This application claims priority to Korean Patent Application No. 10-2022-0089683, filed on Jul. 20, 2022, and all the benefits accruing therefrom under 35 U.S.C. § 119, the content of which in its entirety is herein incorporated by reference.

### BACKGROUND

### 1. Field

The disclosure relates to a neutral beam annealing apparatus and a method of manufacturing a display apparatus by the neutral beam annealing apparatus, and more particularly, to a neutral beam annealing apparatus to form a high-quality thin-film layer, and a method of manufacturing a display apparatus by the neutral beam annealing apparatus.

### 2. Description of the Related Art

In general, in display apparatuses such as organic light-emitting display apparatuses, a plurality of thin-film transistors may be formed on a substrate. The thin-film transistors each include a semiconductor layer, a source electrode, a drain electrode, a gate electrode, and the like and thus may include a thin-film layer formed using an atomic layer deposition apparatus. An annealing process is desired to be performed to improve electrical characteristics of the thin-film layer.

### SUMMARY

When an organic film is used as a substrate of a display apparatus, a temperature of the organic film increases during a process of annealing a thin-film layer by an existing annealing apparatus, and thus, the organic film is damaged. The disclosure is to solve various problems including the aforementioned one and provides a neutral beam annealing apparatus, in which damage to a substrate is reduced and a high-quality thin-film layer is realized, and a method of manufacturing a display apparatus by the neutral beam annealing apparatus. However, this is merely one of embodiments, and the scope of the disclosure is not limited thereto.

Additional features will be set forth in part in the description which follows and, in part, will be apparent from the description, or may be learned by practice of the presented embodiments of the disclosure.

In an embodiment of the disclosure, a neutral beam annealing apparatus includes a plasma chamber having a cylinder shape, a first gas supplier which supplies, inside the plasma chamber, a first gas for forming plasma, a first electrode coupled to an upper surface of the plasma chamber, an induction coil which is wound around an outer circumference of the plasma chamber and receives a high-frequency voltage from a high-frequency power supply, a second electrode which faces the first electrode and is coupled to a lower surface of the plasma chamber, and in which through holes are defined, a substrate support which supports a substrate to be annealed and adjusts a vertical distance between the substrate and the second electrode, an annealing chamber which accommodates the substrate support, and a pressure controller which supplies a second gas to the annealing chamber and adjusts a pressure in the annealing chamber.

In an embodiment, a distance between the upper surface of the substrate and the second electrode may satisfy Equation 1 below:

$${E}_{NB} = {V}_{th} \times {e}^{( - \frac{X}{L} )} \qquad [ Equation 1 ]$$

where X indicates the distance between the upper surface of the substrate and the second electrode, E_{NB} indicates energy of neutral particles reaching the upper surface of the substrate, Vₜₕ indicates a plasma sheath voltage, and L indicates a mean free path of the second gas in the annealing chamber.

In an embodiment, the energy (E_{NB}) of the neutral particles reaching the upper surface of the substrate may be from about 0.05 electronvolt (eV) to about 1 eV.

In an embodiment, a second voltage applied to the second electrode may be less than or equal to about 1 volt (V).

In an embodiment, the second electrode may be floated.

In an embodiment, the second gas may include an inert gas.

In an embodiment, the second gas may include an argon (Ar) gas.

In an embodiment, the first gas may include an Ar gas.

In an embodiment, the second electrode may include a carbon plate.

In an embodiment of the disclosure, a method of manufacturing a display apparatus, includes forming a thin-film layer on a substrate, and annealing, by the neutral beam annealing apparatus according to any one of the embodiments, the thin-film layer formed on the substrate accommodated in the annealing chamber.

Other features and advantages other than those described above will become apparent from the following detailed description, claims and drawings for carrying out the disclosure.

### BRIEF DESCRIPTION OF THE DRAWINGS

The above and other features and advantages of predetermined embodiments of the disclosure will be more apparent from the following description taken in conjunction with the accompanying drawings, in which:

FIG. 1 is a side conceptual view schematically showing an embodiment of a neutral beam annealing apparatus;

FIG. 2 is a side conceptual view schematically showing a portion of a second electrode of the neutral beam annealing apparatus of FIG. 1;

FIG. 3 is a conceptual view of a method of adjusting the energy of a neutral beam irradiated onto a substrate from the neutral beam annealing apparatus of FIG. 1;

FIG. 4 is a graph showing a result of a temperature simulation according to depths of a thin-film layer when the thin-film layer is annealed by an embodiment of a neutral beam annealing apparatus and comparative examples annealing apparatuses;

FIGS. 5 and 6 are conceptual views showing an embodiment of a process of forming a thin-film layer on a substrate by an atomic layer deposition apparatus and a neutral beam annealing apparatus; and

FIG. 7 is a schematic cross-sectional view of an embodiment of a portion of a display apparatus manufactured according to a method of manufacturing a display apparatus.

### DETAILED DESCRIPTION

Reference will now be made in detail to embodiments, embodiments of which are illustrated in the accompanying drawings, where like reference numerals refer to like elements throughout. In this regard, the illustrated embodiments may have different forms and should not be construed as being limited to the descriptions set forth herein. Accordingly, the embodiments are merely described below, by referring to the drawing figures, to explain features of the description. As used herein, the term “and/or” includes any and all combinations of one or more of the associated listed items. Throughout the disclosure, the expression “at least one of a, b, or c” indicates only a, only b, only c, both a and b, both a and c, both b and c, all of a, b, and c, or variations thereof.

As the disclosure allows for various changes and numerous embodiments, particular embodiments will be illustrated in the drawings and described in detail in the written description. The attached drawings for illustrating preferred embodiments of the disclosure are referred to in order to gain a sufficient understanding of the disclosure, the merits thereof, and the objectives accomplished by the implementation of the disclosure. The disclosure may, however, be embodied in many different forms and should not be construed as being limited to the embodiments set forth herein.

Hereinafter, embodiments of the disclosure will be described in detail with reference to the accompanying drawings. Like elements in the drawings denote like elements, and repeated descriptions thereof are omitted.

It will be understood that although the terms “first,” “second,” etc., may be used herein to describe various elements, these elements should not be limited by these terms, and these elements are only used to distinguish one element from another.

As used herein, the singular forms “a,” “an,” and “the” are intended to include the plural forms as well, unless the context clearly indicates otherwise.

It will be further understood that the terms “comprises” and/or “comprising” used herein specify the presence of stated features or elements, but do not preclude the presence or addition of one or more other features or elements.

It will be understood that when a layer, region, or element is referred to as being “formed on” another layer, region, or element, it can be directly or indirectly formed on the other layer, region, or element. That is, for example, intervening layers, regions, or elements may be present.

It will be understood that when a layer, region, or component is referred to as being connected to another layer, region, or component, it can be directly or indirectly connected to the other layer, region, or component. For example, when a layer, region, or component is referred to as being electrically connected to another layer, region, or component, it can be directly or indirectly electrically connected to the other layer, region, or component.

In the illustrated embodiment, an expression such as “A and/or B” indicates A, B, or A and B. Also, an expression such as “at least one of A and B” indicates A, B, or A and B.

In the following examples, the x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

When an embodiment may be implemented differently, a predetermined process order may be performed differently from the described order. For example, two consecutively described processes may be performed substantially at the same time or performed in an order opposite to the described order.

Sizes of elements in the drawings may be exaggerated for convenience of explanation. In other words, since sizes and thicknesses of elements in the drawings are arbitrarily illustrated for convenience of explanation, the following embodiments are not limited thereto.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within ±30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

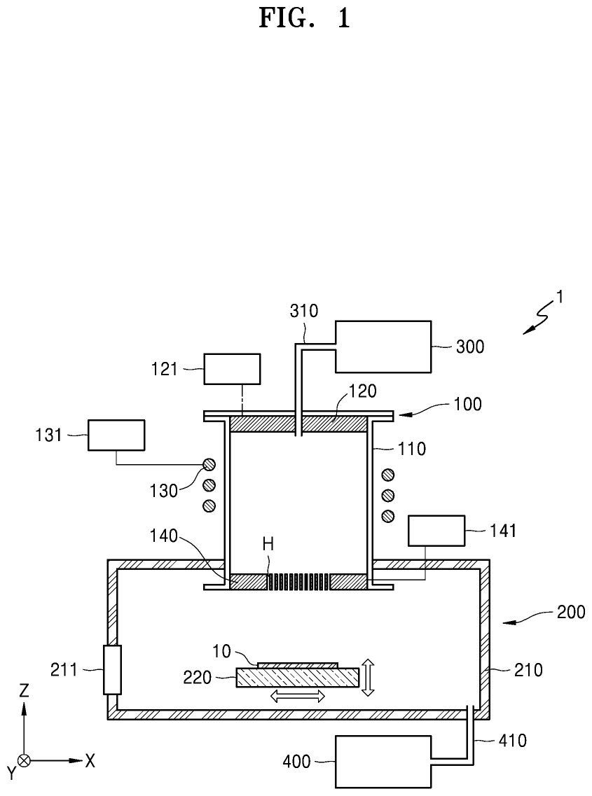

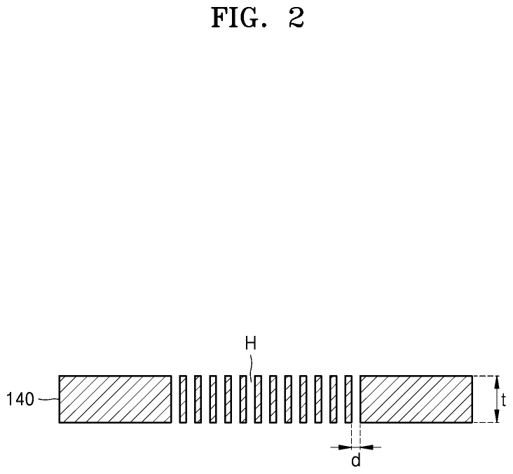

FIG. 1 is a side conceptual view schematically showing an embodiment of a neutral beam annealing apparatus, and FIG. 2 is a side conceptual view schematically showing an embodiment of a portion of a second electrode of the neutral beam annealing apparatus of FIG. 1.

Referring to FIG. 1, a neutral beam annealing apparatus 1 may include a neutral beam generator 100, a neutral beam decelerator 200, a gas supplier 300, and a pressure controller 400.

The neutral beam generator 100 may include a plasma chamber 110, a first electrode 120, induction coils 130, and a second electrode 140. A space where plasma is generated may be defined in the plasma chamber 110, and the plasma chamber 110 may have a cylindrical shape.

The first electrode 120 may be coupled to an upper portion of the plasma chamber 110. The first electrode 120 may receive a first voltage from a first power supply 121. The second electrode 140 may face the first electrode 120 and may be coupled to a lower portion of the plasma chamber 110. In an embodiment, the first electrode 120 may be parallel with the second electrode 140. The second electrode 140 may receive a second voltage from a second power supply 141. A plurality of through holes H penetrating the second electrode 140 may be defined in the second electrode 140.

The second electrode 140 may include a material that is less likely to contaminate a thin-film layer on a substrate 10 because of a low sputtering yield even when high-energy particles collide with the second electrode 140. In an embodiment, the second electrode 140 may be a carbon plate electrode.

As shown in FIG. 2, the through holes H of the second electrode 140 may have high aspect ratios. In an embodiment, a thickness t of the second electrode 140 may be greater than a diameter d of the through hole H, for example. In an embodiment, the thickness t of the second electrode 140 may be about 1.7 times to about 10 times the diameter d of the through hole H. Ion particles discharged from high-density plasma generated inside the plasma chamber 110 may pass through the through holes H of the second electrode 140 and may be neutralized by exchanging charges with a surface of the second electrode 140.

The induction coils 130 may be arranged along an outer circumference of the plasma chamber 110. The induction coils 130 may be wound around an outer circumferential surface of the plasma chamber 110 multiple times. The induction coil 130 may be electrically connected to a high-frequency power supply 131 and receive a high-frequency voltage.

A portion of the plasma chamber 110 is designed to be open so that the plasma chamber 110 may be connected to the gas supplier 300 through a first pipe 310. In this case, the first pipe 310 may include a device or a structure, e.g., a gate valve, which may open and close an opening.

The gas supplier 300 may be disposed outside the plasma chamber 110 and supply a first gas for forming plasma to the inside of the plasma chamber 110. In this case, the first gas may include various gases. In an embodiment, the first gas may include an inert gas. The first gas may include argon (Ar), for example.

The neutral beam decelerator 200 may be disposed under the neutral beam generator 100. The neutral beam decelerator 200 may include an annealing chamber 210 and a substrate support 220. As shown in FIG. 1, at least a portion of the plasma chamber 110 may be inserted into the annealing chamber 210.

The annealing chamber 210 may have an internal space where the substrate 10 is accommodated and neutral beams decelerate, and an opening to be exposed to the outside may be defined in the annealing chamber 210. In an embodiment, a chamber gate 211 may be on one side of the annealing chamber 210 to insert or discharge the substrate 10, for example.

The substrate support 220 may be moved in a horizontal direction (e.g., an x-axis direction) and a vertical direction (e.g., a z-axis direction). The substrate 10 may be disposed on the substrate support 220 and moved in the horizontal direction and the vertical direction according to a movement of the substrate support 220.

Also, the annealing chamber 210 may be connected to the pressure controller 400 through a second pipe 410. In this case, the second pipe 410 may include a device or a structure, e.g., a gate valve, which may open and close an opening.

The pressure controller 400 may supply a second gas to the annealing chamber 210 and adjust an internal pressure of the annealing chamber 210. The pressure controller 400 may include an exhaust pipe and/or a second gas supplier. Gas particles in the second gas may collide with neutral particles constituting neutral beams and attenuate the energy of the neutral particles. In an embodiment, the second gas may include various gases. In an embodiment, the second gas may include an inert gas. The second gas may include Ar, for example.

By applying a high-frequency voltage RF to the induction coils 130, plasma may be generated from the first gas in the plasma chamber 110. Ions discharged from the plasma may pass through the through holes H of the second electrode 140 and may be neutralized by exchanging charges with the surface of the second electrode 140. Neutral beams (neutral particle beams) discharged from the through holes H of the second electrode 140 may have a high energy of about 20 electronvolts (eV) or greater, but may lose energy because of a collision with second gas particles in the annealing chamber 210. Therefore, the neutral beam annealing apparatus 1 in an embodiment may adjust a distance from the second electrode 140 to an upper surface of the substrate 10 and a pressure of the second gas inside the annealing chamber 210, thus annealing an uppermost surface of the thin-film layer disposed on the substrate 10. In the specification, the uppermost surface of the thin-film layer indicates a depth of several angstroms (Å) to several nanometers (nm) from a surface of the thin-film layer.

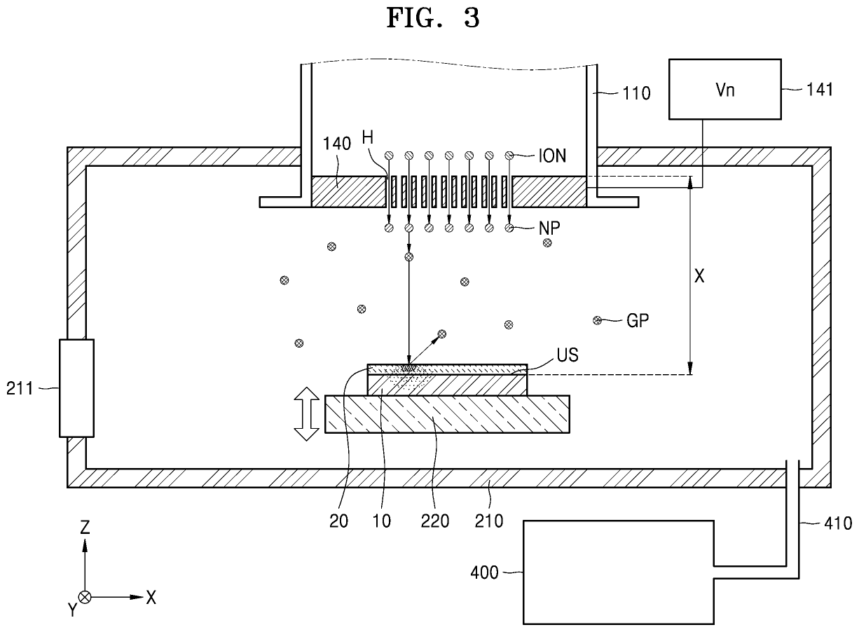

FIG. 3 is a conceptual view of a method of adjusting an energy of a neutral beam irradiated onto a substrate from the neutral beam annealing apparatus of FIG. 1;

Referring to FIG. 3, ions ION may move from the plasma generated in the plasma chamber 110 to the annealing chamber 210 through the through holes H of the second electrode 140.

The ions ION may be neutralized by exchanging charges with the surface of the second electrode 140 while passing through the through holes H of the second electrode 140. That is, as shown in FIG. 3, the ions ION may pass through the second electrode 140 and become neutral particles NP. In this case, the second electrode 140 may be electrically connected to the second power supply 141 and receive a second voltage Vn. In an embodiment, the second voltage Vn may be less than or equal to about 1 V. In an alternative embodiment, the second electrode 140 may be in a floating state in which the second electrode 140 is insulated from an external power supply. In an embodiment, a potential difference between the first electrode 120 (refer to FIG. 1) and the second electrode 140 may be less than or equal to about 1 V. While the second voltage Vn of less than or equal to about 1 volt (V) is applied to the second electrode 140 or while the second electrode 140 is floated, the ions ION may accelerate because of a plasma sheath potential difference made according to a mobility difference between electrons and ions, and thus, the neutral particles NP discharged from the second electrode 140 may have an energy of about 20 eV.

The substrate 10 may be disposed on the substrate support 220 arranged in the annealing chamber 210. The substrate support 220 may be moved in the horizontal direction (e.g., the x-axis direction) and the vertical direction (e.g., a y-axis direction) and thus may move the substrate 10. During the annealing process, the substrate 10 may be disposed under the plasma chamber 110.

The substrate 10 may include a glass material, metals, or an organic material. In an embodiment, the substrate 10 may include a flexible material. In an embodiment, the substrate 10 may include polymer resin such as polyethersulphone, polyacrylate, polyetherimide, polyethylene naphthalate, polyethylene terephthalate, polyphenylene sulfide, polyarylate, polyimide, polycarbonate, or cellulose acetate propionate, for example.

A thin-film layer 20 on an upper surface US of the substrate 10 may have a thickness of about several A to several nm. In an embodiment, the thin-film layer 20 may be formed using an atomic layer deposition apparatus. The thin-film layer 20 may be an oxide semiconductor layer used to form a thin-film transistor. In an embodiment, the thin-film layer 20 may include an indium gallium zinc oxide (“IGZO”) semiconductor, an indium tin zinc oxide (“ITZO”) semiconductor, and an indium tin gallium zinc oxide (“ITGZO”) semiconductor including metals such as indium (In), gallium (Ga), and tin (Sn), for example. In an alternative embodiment, the thin-film layer 20 may be a transparent conductive layer. In an embodiment, the thin-film layer 20 may include transparent conductive oxide such as indium tin oxide (“ITO”), indium zinc oxide (“IZO”), zinc oxide (ZnO), or ITZO, for example. In an alternative embodiment, the thin-film layer 20 may be a conductive layer including copper (Cu) or aluminum (Al).

The neutral particles NP may collide with second gas particles GP in the annealing chamber 210 and lose the energy. As described above, the second gas particles GP may be inert gas particles. In an embodiment, the second gas particles GP may be Ar gas particles, for example. The second gas particles GP may be provided to the inside of the annealing chamber 210 or discharged to the outside thereof by the pressure controller 400. That is, the pressure controller 400 may adjust a pressure of the second gas in the annealing chamber 210.

As described above, when the substrate 10 includes a flexible material, the substrate 10 may be vulnerable to heat. Therefore, the neutral particles NP colliding with the upper surface US of the substrate 10 may have an energy ranging from about 0.05 eV to about 1 eV to heat only the uppermost surface of the thin-film layer 20 disposed on the upper surface US of the substrate 10 and having a thickness of about several Å to about several nm.

The energy of the neutral particles NP reaching the upper surface US of the substrate 10 may satisfy Equation 1 below.

$${E}_{NB} = {V}_{th} \times {e}^{( - \frac{X}{L} )} \qquad [ Equation 1 ]$$

In this case, X may indicate a distance from the second electrode 140 to the upper surface US of the substrate 10, E_{NB} may indicate the energy of the neutral particles NP reaching the upper surface US of the substrate 10, Vₜₕ may indicate a plasma sheath voltage, and L may indicate a mean free path of the second gas in the annealing chamber 210.

In an embodiment, the energy of the neutral particles NP reaching the upper surface US of the substrate 10 may be adjusted as the pressure controller 400 adjusts the pressure of the second gas in the annealing chamber 210 to change a mean free path L of the second gas or adjusts a distance X from the second electrode 140 to the upper surface US of the substrate 10 by moving the substrate support 220 in a vertical direction, for example.

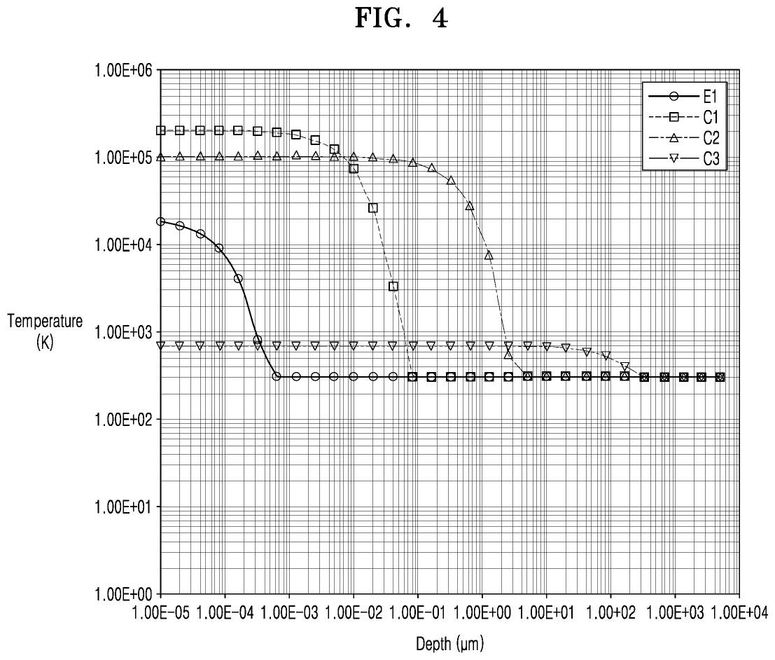

FIG. 4 is a graph showing a temperature simulation according to a depth of a thin-film layer when the thin-film layer is annealed using an embodiment of the neutral beam annealing apparatus and Comparative Examples of annealing apparatuses. Experimental Example E1 of FIG. 4 shows a temperature simulation result when a thin-film layer is annealed using the neutral beam annealing apparatus in an embodiment of the disclosure, and Comparative Example C1 to Comparative Example C3 respectively show temperature simulation results according to a depth of a thin-film layer in a vertical direction from a surface thereof when the thin-film layer is annealed using ions, laser beams, and an infrared (“IR”) heater. Here, the thin-film layer is an ITO layer.

Referring to FIG. 4, in Experimental Example E1 using the neutral beam annealing apparatus, in a depth of about 10 Å or greater from the surface of the thin-film layer, a temperature of the thin-film layer does not increase.

On the contrary, according to Comparative Example C1 showing an annealing process using ions, a temperature of a thin-film layer increases to a depth of about 0.1 micrometer (μm) from the surface of the thin-film layer. The annealing process using the ions is to heat the thin-film layer by accelerating the ions themselves to cause the collision between the ions and the surface of the thin-film layer, which desires the acceleration of about 10 kiloelectronvolts (KeV) or greater in an ultra-vacuum. Because high energy is used, the ions may be injected into the thin-film layer and a substrate thereunder, and thus, the annealing process using the ions may not be appropriate to anneal the thin-film layer. Also, it may be impossible to adjust an energy level to be lower than or equal to about 10 eV because of a plasma sheath potential difference.

According to Comparative Example C2 showing an annealing process using laser beams, a temperature of a thin-film layer increases to a depth of several μm from the surface of the thin-film layer. The energy of photons in a laser beam having a wavelength of about 200 nm to about 400 nm ranges from about 3.5 eV to about 4.5 eV, which is lower than the energy of ions. However, according to the wavelengths of laser beams, laser beams having a wavelength of about 10 nm or greater may penetrate a silicon (Si) thin film, and laser beams having a wavelength of about 1 nm or greater may penetrate an ITO thin film, and the annealing process using laser beams is not appropriate to anneal an ultra-thin film accordingly.

According to Comparative Example C3 showing an annealing process using an IR heater, a temperature of a thin-film layer increases to a depth of about several hundred μm from the surface of the thin-film layer. Because IR rays penetrate the thin-film layer and the substrate and heat the same, it is impossible to heat only the thin-film layer.

As described above, when the substrate is flexible, the substrate may be damaged by heat, and thus, there is a need to selectively anneal the thin-film layer, of which a thickness is about several Å to about several nm, without increasing the temperature of the substrate. In the neutral beam annealing apparatus in embodiments, neutral particles, which have high energy sufficient enough to selectively heat the surface of the thin-film layer, are used, and thus, thermal damage to the substrate may be prevented or reduced. In addition, because the neutral particles are used, the thin-film layer or the surface of the substrate may be prevented from being charged up.

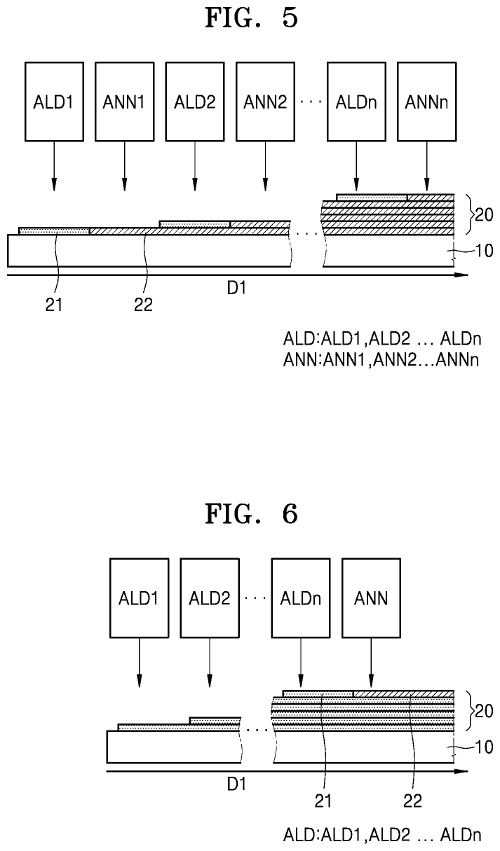

FIGS. 5 and 6 are conceptual views respectively showing an embodiment of a process of forming a thin-film layer on a substrate by an atomic layer deposition apparatus and a neutral beam annealing apparatus. FIGS. 5 and 6 show that the substrate 10 is moved in one direction D1 and the thin-film layer 20 is formed on the substrate 10 and annealed, but the disclosure is not limited thereto.

Referring to FIGS. 5 and 6, to form the thin-film layer 20 on the substrate 10, a plurality of atomic layer deposition apparatuses ALD may be arranged along a direction in which the substrate 10 is moved. Each of the atomic layer deposition apparatuses ALD may deposit a new atomic layer 21 on the substrate 10 or the thin-film layer 20 that is formed by atomic layer deposition apparatuses previously arranged.

As shown in FIG. 5, neutral beam annealing apparatuses ANN in an embodiment may be arranged along the direction, in which the substrate 10 is moved, to anneal the atomic layers 21 forming the thin-film layer 20. In an embodiment, the atomic layer deposition apparatuses ALD and the neutral beam annealing apparatuses ANN may be alternately arranged.

In an embodiment, one atomic layer 21 may be formed on the substrate 10 passing a first atomic layer deposition apparatus ALD1, for example. The above atomic layer 21 may be annealed by passing a first neutral beam annealing apparatus ANN1 as the substrate 10 is moved in a direction D1. As the substrate 10 is moved in the direction D1, another atomic layer 21 may be formed on an atomic layer 22 that is annealed by passing a second atomic layer deposition apparatus ALD2.

Because the neutral beam annealing apparatus ANN may provide heat only to a depth of several Å to about several nm, the atomic layer deposition apparatuses ALD and the neutral beam annealing apparatuses ANN may be arranged to obtain the thin-film layer 20 having a sufficient thickness and annealed, as shown in FIG. 5.

In an alternative embodiment, as shown in FIG. 6, to form a thin-film layer 20 having a desired configuration and a desired thickness, a plurality of atomic layer deposition apparatuses ALD may be arranged in the direction in which the substrate 10 is moved. To anneal an atomic layer 21 at a desired location, a neutral beam annealing apparatus ANN may be arranged between the atomic layer deposition apparatuses ALD or after the last atomic layer deposition apparatus ALD. The neutral beam annealing apparatus ANN may anneal one or more atomic layers 21 disposed on an uppermost portion of the thin-film layer 20 and convert the one or more atomic layers 21 to an annealed atomic layer 22 having improved crystallinity. FIG. 6 shows that one neutral beam annealing apparatus ANN is arranged after an n^{th} atomic layer deposition apparatus ALDn, but one or more neutral beam annealing apparatuses ANN may be further arranged between the atomic layer deposition apparatuses ALD.

Although not shown in FIGS. 5 and 6, an atomic layer etching apparatus (not shown) may be further arranged between the atomic layer deposition apparatuses ALD and the neutral beam annealing apparatuses ANN. As described, pressure controllers, gas suppliers, exhaust pipes, or the like may also be arranged in the atomic layer deposition apparatuses ALD and the neutral beam annealing apparatuses ANN, respectively.

FIGS. 5 and 6 show that the substrate 10 is moved in the direction D1 and processes are consecutively performed, but the processes may be separated and non-consecutively performed. In an alternative embodiment, the substrate 10 may be fixed in a chamber, and each process may be performed while a process gas and a vertical location of the substrate 10 are only adjusted.

The neutral beam annealing apparatus is mainly described, but the disclosure is not limited thereto. In an embodiment, a method of manufacturing a display apparatus by a neutral beam annealing apparatus is included in the scope of the disclosure as well, for example.

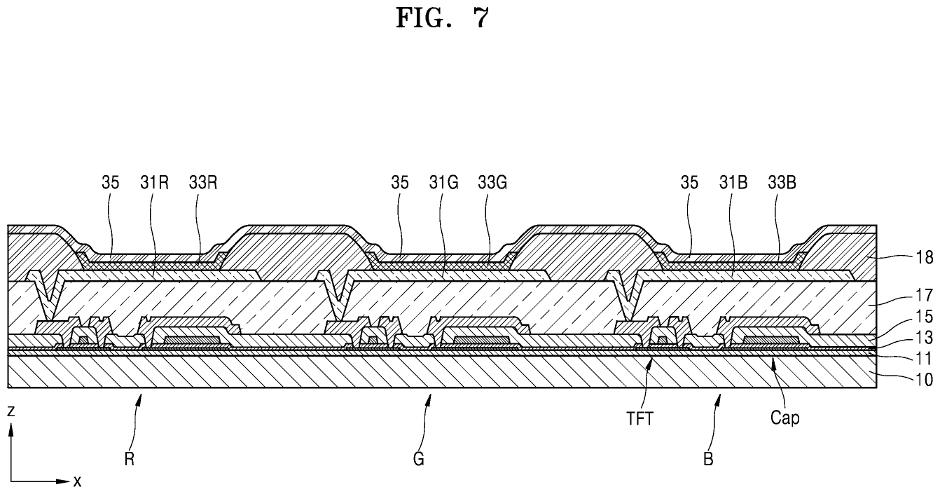

FIG. 7 is a schematic cross-sectional view of an embodiment of a portion of a display apparatus manufactured according to a method of manufacturing a display apparatus.

Common layers including a buffer layer 11, a gate insulating layer 13, an inter-insulating layer 15, or the like may be formed on an entirety of the substrate 10, and a semiconductor layer including polysilicon or an oxide semiconductor may also be formed on the substrate 10. Also, a thin-film transistor TFT including a semiconductor layer, a gate electrode, a source electrode, and a drain electrode may be formed on the substrate 10.

The semiconductor layer may be formed on the substrate 10 and then gate electrodes, source electrodes, drain electrodes, or the like are formed to form thin-film transistors TFT. When the thin-film transistors TFT are formed, capacitors Cap, lines, etc., may be simultaneously formed by the same material as that of the thin-film transistors TFT.

A planarization layer 17 covering the thin-film transistors TFT and having a substantially flat upper surface is formed on an entirety of the substrate 10. Organic light-emitting diodes electrically connected to the thin-film transistors TFT are formed on the planarization layer 17. The organic light-emitting diodes may include pixel electrodes 31R, 31G, and 31B patterned, an opposite electrode 35 substantially corresponding to the entirety of the substrate 10, and intermediate layers 33R, 33G, and 33B arranged between the pixel electrodes 31R, 31G, and 31B and the opposite electrode 35, including emission layers, and having multilayered structures. Unlike the illustration that the intermediate layers 33R, 33G, and 33B are patterned to respectively correspond to the pixel electrodes 31R, 31G, and 31B, layers such as a hole injection layer, a hole transport layer, and an electron transport layer may be common layers substantially corresponding to the entirety of the substrate 10, and other layers such as emission layers may be layers patterned to correspond to the pixel electrodes 31R, 31G, and 31B. The pixel electrodes 31R, 31G, and 31B may be electrically connected to the thin-film transistors TFT through via holes. A pixel-defining layer covering edges of the pixel electrodes 31R, 31G, and 31B and having openings defining respective pixel regions may be formed on the planarization layer 17 to substantially correspond to the entirety of the substrate 10.

As described, during the manufacture of an organic light-emitting display apparatus including red sub-pixels R, green sub-pixels G, and/or blue sub-pixels B, at least a portion of the thin-film layer may be formed by the neutral beam annealing apparatus in the embodiments.

In an embodiment, the thin-film layer may be an IGZO semiconductor layer, an ITZO semiconductor layer, or an ITGZO semiconductor layer including metals such as In, Ga, and Sn, a transparent conductive layer including transparent conductive oxide such as ITO, IZO, ZnO, or ITZO, or a conductive layer including Cu or Al, for example.

The thin-film layer may be patterned and form components of the thin-film transistors TFT or the organic light-emitting diodes electrically connected to the thin-film transistors TFT.

As described, it may be construed that the method of manufacturing a display apparatus is included in the scope of the disclosure, the method including forming the thin-film layer on the substrate 10, forming, on the thin-film layer, another thin-film layer having improved crystallinity by irradiating neutral beams discharged from the neutral beam annealing apparatus in at least one of the embodiments, and forming a display element including the thin-film layer. In the display apparatus manufactured according to the above method, because grains are uniformly produced in a neutral beam annealing process during the manufacture of the display apparatus, electrical conductivity, mobility, and carrier concentration of the thin-film layer may be improved, thereby realizing a high-quality display apparatus.

The disclosure is not limitedly applied to an organic light-emitting display apparatus, and it may be understood that, when a display apparatus is an apparatus, e.g., a liquid crystal display apparatus, which includes a thin-film layer annealed using a neutral beam annealing apparatus, the display apparatus may be included in the scope of the disclosure.

In the embodiments, a neutral beam annealing apparatus, in which damage to a substrate is reduced and a high-quality thin-film layer is produced, and a method of manufacturing a display apparatus by the neutral beam annealing apparatus may be realized. However, the scope of the disclosure is not limited by the effects.

It should be understood that embodiments described herein should be considered in a descriptive sense only and not for purposes of limitation. Descriptions of features or advantages within each embodiment should typically be considered as available for other similar features or advantages in other embodiments. While embodiments have been described with reference to the drawing figures, it will be understood by those of ordinary skill in the art that various changes in form and details may be made therein without departing from the spirit and scope as defined by the following claims.

What is claimed is:

1. A neutral beam annealing apparatus comprising:
a plasma chamber having a cylinder shape;
a first gas supplier which supplies, inside the plasma chamber, a first gas which forms plasma;
a first electrode coupled to an upper surface of the plasma chamber;
an induction coil which is wound around an outer circumference of the plasma chamber and receives a high-frequency voltage from a high-frequency power supply;
a second electrode which faces the first electrode and is coupled to a lower surface of the plasma chamber, and in which a plurality of through holes is defined;
a substrate support which supports a substrate to be annealed and adjusts a vertical distance between the substrate and the second electrode;
an annealing chamber which accommodates the substrate support; and
a pressure controller which supplies a second gas to the annealing chamber and to adjust a pressure in the annealing chamber.

2. The neutral beam annealing apparatus of claim 1, wherein a distance between the upper surface of the substrate and the second electrode satisfies Equation 1 below:
$${E}_{NB} = {V}_{th} \times {e}^{( - \frac{X}{L} )} \qquad [ Equation 1 ]$$
wherein X indicates the distance between the upper surface of the substrate and the second electrode, E_{NB} indicates energy of neutral particles reaching the upper surface of the substrate, Vₜₕ indicates a plasma sheath voltage, and L indicates a mean free path of the second gas in the annealing chamber.

3. The neutral beam annealing apparatus of claim 2, wherein the energy (E_{NB}) of the neutral particles reaching the upper surface of the substrate is from about 0.05 electronvolt to about 1 electronvolt.

4. The neutral beam annealing apparatus of claim 1, wherein a second voltage applied to the second electrode is less than or equal to about 1 volt.

5. The neutral beam annealing apparatus of claim 1, wherein the second electrode is floated.

6. The neutral beam annealing apparatus of claim 1, wherein the second gas comprises an inert gas.

7. The neutral beam annealing apparatus of claim 1, wherein the second gas comprises an argon (Ar) gas.

8. The neutral beam annealing apparatus of claim 1, wherein the first gas comprises an argon (Ar) gas.

9. The neutral beam annealing apparatus of claim 1, wherein the second electrode comprises a carbon plate.

10. A method of manufacturing a display apparatus, the method comprising:
forming a thin-film layer on a substrate; and
annealing, by a neutral beam annealing apparatus, the thin-film layer formed on the substrate accommodated in an annealing chamber,
wherein
the neutral beam annealing apparatus includes:
a plasma chamber having a cylinder shape;
a first gas supplier which supplies, inside the plasma chamber, a first gas for forming plasma;
a first electrode coupled to an upper surface of the plasma chamber;
an induction coil which is wound around an outer circumference of the plasma chamber and receives a high-frequency voltage from a high-frequency power supply;
a second electrode which faces the first electrode and is coupled to a lower surface of the plasma chamber, and in which a plurality of through holes is defined;
a substrate support supporting the substrate to be annealed and adjusting a vertical distance between the substrate and the second electrode;
the annealing chamber for accommodating the substrate support; and
a pressure controller which supplies a second gas to the annealing chamber and to adjust a pressure in the annealing chamber.
